(19) United States
(12) Patent Application Publication
(10) Pub. No.: US 2026/0025928 A1
(43) Pub. Date: Jan. 22, 2026

(54) ELECTRONIC DEVICE

(71) Applicant: Advanced Semiconductor Engineering, Inc., Kaohsiung (TW)

(72) Inventors: Kuei-Hao TSENG, Kaohsiung (TW); Kai Hung WANG, Kaohsiung (TW)

(73) Assignee: Advanced Semiconductor Engineering, Inc., Kaohsiung (TW)

(21) Appl. No.: 18/774,875

(22) Filed: Jul. 16, 2024

(51) Int. Cl. H05K 1/18; H05K 1/11; H05K 5/00

(52) U.S. Cl. CPC H05K 1/183; H05K 1/11; H05K 5/0086

(57) ABSTRACT

The present disclosure provides an electronic device. The electronic device includes a circuit structure, an electronic component, a flexible conductive layer, and a conductive element. The circuit structure has a first surface and a second surface opposite to the first surface. The electronic component is under the first surface. The flexible conductive layer is over the second surface. The conductive element extends toward a direction far away from the second surface and connected to the flexible conductive layer. The conductive element is embedded within at least two different materials.

### BACKGROUND

### 1. Technical Field

The present disclosure relates to an electronic device.

### 2. Description of the Related Art

Electronic devices may be integrated into wearable devices to obtain signals or information reflecting physical activity and/or health. Conventionally, signals or pieces of information detected or collected by the electronic devices are transmitted to processing devices through conductive elements (e.g., wires, cables, circuit layers, etc.). Noise and interference problems exist and become severe with long transmission paths between the electronic devices and the processing devices, affecting transmission properties and sensing quality.

### SUMMARY

In some arrangements, an electronic device includes a circuit structure, an electronic component, a flexible conductive layer, and a conductive element. The circuit structure has a first surface and a second surface opposite to the first surface. The electronic component is under the first surface. The flexible conductive layer is over the second surface. The conductive element extends toward a direction far away from the second surface and connected to the flexible conductive layer. The conductive element is disposed across two materials.

In some arrangements, an electronic device includes a circuit structure, an electronic component, a flexible conductive layer, and a first conductive element. The circuit has a first surface and a second surface. The electronic component is under the first surface. The flexible conductive layer is over the second surface and spaced apart from the circuit structure. The first conductive element is between the flexible conductive layer and the circuit structure.

In some arrangements, an electronic device includes a circuit structure, an electronic component under, and a conductive paste. The circuit structure has a first surface and a second surface. The electronic component is under the first surface. The conductive paste is over the second surface. The conductive paste is configured to detect a bio-signal and has a surface, spaced apart from the circuit structure, with different elevations with respect to the second surface of the circuit structure.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic device in accordance with some arrangements of the present disclosure.

FIG. 2 illustrates a cross-sectional view of an electronic device in accordance with some arrangements of the present disclosure.

FIG. 3 illustrates a cross-sectional view of an electronic device in accordance with some arrangements of the present disclosure.

FIG. 4 illustrates a cross-sectional view of an electronic device in accordance with some arrangements of the present disclosure.

FIG. 5 illustrates a cross-sectional view of an electronic device in accordance with some arrangements of the present disclosure.

FIG. 6 illustrates a cross-sectional view of an electronic device in accordance with some arrangements of the present disclosure.

FIG. 7 illustrates a cross-sectional view of an electronic device in accordance with some arrangements of the present disclosure.

FIG. 8 illustrates a cross-sectional view of an electronic device in accordance with some arrangements of the present disclosure.

FIG. 9 illustrates a cross-sectional view of an electronic device in accordance with some arrangements of the present disclosure.

FIG. 10 illustrates a cross-sectional view of an electronic device in accordance with some arrangements of the present disclosure.

FIG. 11 illustrates a cross-sectional view of an electronic device in accordance with some arrangements of the present disclosure.

FIG. 12 illustrates a perspective view of a wearable device in accordance with some arrangements of the present disclosure.

FIG. 13 illustrates a perspective view of a wearable device in accordance with some arrangements of the present disclosure.

FIG. 14 illustrates a perspective view of a wearable device on a user in accordance with some arrangements of the present disclosure.

FIG. 15 illustrates a cross-sectional view of an electronic device in accordance with some arrangements of the present disclosure.

FIG. 16 illustrates a perspective view of a wearable device on a user in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

FIG. 1 illustrates a cross-sectional view of an electronic device 1a in accordance with some arrangements of the present disclosure. In some arrangements, the electronic device 1a may include or be a part of an electronic device package or an electronic device module, such as a system-in-package (SiP) module. In some arrangements, the electronic device 1a may include or be a part of a wearable device. For example, the electronic device 1a may be configured to be worn by and/or attached to an object or a target. The object (or a wearing object) may include a human or an animal.

The electronic device 1a may also be referred to as a monitoring device, a detecting device, or a sensing device. In some arrangements, the electronic device 1a may be a piece of equipment that detects signals or pieces of information, such as biological signals, physiological signals, motions (e.g., body motions of the human or animal), and/or environmental information in a vicinity of an object.

Configuration or application of the electronic device 1a in the figures is for illustrative purposes only, and not intended to limit the present disclosure. Exemplary electronic devices may be embodied in an earpiece, a headpiece, a finger clip, a digit (finger or toe) piece, a watch, a limb band (such as an arm band or leg band), an ankle band, a wrist band, a nose piece, a sensor patch, eyewear (such as glasses or shades), apparel (such as a shirt, hat, underwear, etc.), a mouthpiece or tooth piece, contact lenses, or the like.

In some arrangements, the electronic device 1a may include a circuit structure 10, electronic components 20a and 20b, electrical connectors 30, an encapsulant 40, conductive elements 50, an encapsulant 60a, and a flexible conductive layer 70a.

The circuit structure 10 may include a substrate. The circuit structure 10 may include a printed circuit board (PCB), such as a paper-based copper foil laminate, a composite copper foil laminate, or a polymer-impregnated glass-fiber-based copper foil laminate. In some arrangements, the circuit structure 10 may include an interconnection structure, such as a redistribution layer (RDL) or a grounding element.

The circuit structure 10 may include a surface 10s1 (or a lower surface), a surface 10s2 opposite (or an upper surface) to the surface 10s1, and a surface 10s3 (or a lateral surface) extending between the surface 10s1 and the surface 10s2. The circuit structure 10 may include one or more conductive pads (not shown) in proximity to, adjacent to, or embedded in and exposed from the surface 10s1 and/or surface 10s2 of the circuit structure 10. The circuit structure 10 may include a solder resist (not shown) on the surface 10s1 and/or surface 10s2 of the circuit structure 10 to fully expose or to expose at least a portion of the conductive pads for electrical connections.

The circuit structure 10 may include or define one or more holes 10h. The holes 10h may form a circle from a top view. However, in some arrangements, the holes 10h may form an oval, a square, a rectangle, a triangle, or other shapes. The holes 10h may be equally or randomly spaced from the top view. The holes 10h may include inner through holes and may not be exposed from the surface 10s3. The holes 10h may each include a constant width. However, in some arrangements, one or more of the holes 10h may taper toward the surface circuit structure 101 or taper toward the surface 10s2. The holes 10h may at least partially penetrate the circuit structure 10. For example, the holes 10h may extend between the surface 10s1 and the surface 10s2. However, in some arrangements, the holes 10h may include blind via holes 10h. For example, the holes 10h may have bottoms at an elevation between the surface 10s1 and the surface 10s2. In some arrangements, the holes 10h may be filled with the encapsulant 40 and/or encapsulant 60a. The holes 10h filled with the encapsulant 40 and/or encapsulant 60a may function as lock and key elements or interlocking mechanical features. Therefore, the adhesion force or a bonding strength between the circuit structure 10 and the encapsulant 40 and/or encapsulant 60a may be increased.

In some arrangements, the electronic components 20a and 20b may be disposed on or under the surface 10s1 of the circuit structure 10. The electronic components 20a and 20b may each be electrically connected to the circuit structure 10 (e.g., to the RDL), and electrical connection may be attained by way of flip-chip bonding (e.g., solder bonding), wire bonding, Cu-to-Cu bonding, or hybrid bonding.

The electronic components 20a and 20b may each be a chip or a die including a semiconductor substrate, one or more integrated circuit (IC) devices and one or more overlying interconnection structures therein.

In some arrangements, the electronic components 20a and 20b may each include an active component, which may rely on an external power supply to control or modify electrical signals. For example, the electronic components 20a and 20b may each include a processor, a controller, a memory, or an input/output (I/O) buffer, etc. For example, the electronic components 20a and 20b may each include a central processing unit (CPU), a microprocessor unit (MPU), a graphics processing unit (GPU), a microcontroller unit (MCU), an application-specific integrated circuit (ASIC), a field-programmable gate array (FPGA), or another type of computing element or integrated circuit.

In some arrangements, the electronic components 20a and 20b may each include a passive component, which may not require an external power source to function and may not provide electrical gain. For example, the electronic components 20a and 20b may each include a resistor, a capacitor, an inductor, a transformer, a diode, a thermistor, a varactor, a transducer, etc.

The functions and number of the electronic components in the electronic device 1a are not intended to limit the present disclosure. For example, there may be any number of the electronic components in the electronic device 1a due to design requirements.

In some arrangements, the electrical connectors 30 (or terminals) may be disposed on or under the surface 10s1 of the circuit structure 10. In some arrangements, the electrical connector 30 may be electrically connected to an external device (not shown) of a wearable device. In some arrangements, the electrical connector 30 may be disposed at a peripheral region of the surface 10s1. For example, the electrical connector 30 may be closer to the surface 10s3 of the circuit structure 10 than the electronic component 20a (or electronic component 20b) is. In some arrangements, the electrical connectors 30 may surround the electronic components 20a and 20b. In some arrangements, the electrical connector 30 may include a solder ball, such as a controlled collapse chip connection (C4) bump, a ball grid array (BGA), a land grid array (LGA), and so on. The electrical connector 30 may include a solder material(s), which may include alloys of gold and tin solder or alloys of silver and tin solder, or other suitable materials.

In some arrangements, the encapsulant 40 may be disposed on or under the surface 10s1 of the circuit structure 10. In some arrangements, the encapsulant 40 may encapsulate the electronic components 20a and 20b. In some arrangements, the encapsulant 40 may encapsulate the electrical connectors 30. In some arrangements, a portion of the electrical connector 30 may be exposed by the encapsulant 40. The encapsulant 40 may include, for example, rubber, silicon, polyester, polyurethane, or other suitable materials such as an elastic material, a soft material, a sponge-like material, or a flexible material. In some arrangements, the encapsulant 40 may include a liquid silicone rubber (LSR) or fluoroelastomer (FKM). In some arrangements, the encapsulant 40 may have a substantially uniform thickness with respect to the surface 10s1 of the circuit structure 10.

In some arrangements, the encapsulant 40 may be configured to be adjustable. The encapsulant 40 may each be soft and flexible enough for the object to be worn comfortably for an extended time period. In some arrangements, the encapsulant 40 may each be relatively more resistant to stress, impact, twisting or other physical or structural changes. For example, the encapsulant 40 may each be resilient, such that, after being squeezed or deformed, an encapsulant can return to its original state. In some arrangements, the encapsulant 40 may each flexibly adjust its shape to conform to the body of a user. In some arrangements, the encapsulant 40 may be configured to directly contact the body of a user. The encapsulant 40 may each be bio-compatible. For example, the encapsulant 40 may each not being toxic, injurious, or physiologically reactive and not causing immunological rejection.

In some arrangements, the conductive elements 50 may be disposed on or over the surface 10s2 of the circuit structure 10. The conductive element 50 may be electrically connected to the circuit structure 10. In some arrangements, the conductive element 50 may be electrically connected to the electronic component 20a (or electronic component 20b) through the circuit structure 10. The conductive element 50 may extend toward a direction far away from the surface 10s2 and connected to the flexible conductive layer 70a. In some arrangements, the conductive element 50 may be disposed across two or more different materials (e.g., the encapsulant 60a and the flexible conductive layer 70a and/or other materials such as an adhesive between the encapsulant 60a and the flexible conductive layer 70a). In some arrangements, the conductive element 50 may be electrically connected to the electrical connector 30 through the circuit structure 10. In some arrangements, the electrical connector 30 may have a relatively small resistance. For example, the resistance of the material of the electrical connector 30 may be less than that of a conductive paste which includes conductive fillers within a polymer, a resin, or other flexible mediums. In some arrangements, the conductive element 50 may include copper (Cu) or other conductive materials, such as aluminum (Al), chromium (Cr), tin (Sn), gold (Au), silver (Ag), nickel (Ni), stainless steel, another metal, or a mixture, an alloy, or other combinations of two or more thereof. Each of the conductive elements 50 may have an end 50e1 and an end 50e2. In some arrangements, the end 50e1 may be in contact with or electrically connected to the surface 10s2 of the circuit structure 10. In some arrangements, the end 50e2 may be in contact with or electrically connected to the surface 10s2 of the circuit structure 10. In some arrangements, the conductive element 50 may include a conductive wire which is bendable. In some arrangements, a portion of the conductive element 50 may be protruded from the encapsulant 60a.

In some arrangements, the encapsulant 60a may be disposed on or over the surface 10s2 of the circuit structure 10. In some arrangements, the encapsulant 60a may encapsulate a portion of the conductive element 50. In some arrangements, a portion of the conductive element 50 may exceed a surface 60s1 (or an upper surface) of the encapsulant 60a. The encapsulant 60a may have a surface 60s2 (or a lateral surface) connected to the surface 60s1. In some arrangements, the surface 60s2 of the encapsulant 60a may be substantially aligned with the surface 10s3 of the circuit structure 10. In some arrangements, the encapsulant 60a may be configured to support the flexible conductive layer 70a. In some arrangements, the encapsulant 60a may include, for example, rubber, silicon, polyester, polyurethane, or other suitable materials such as an elastic material, a soft material, a sponge-like material, or a flexible material. In some arrangements, the encapsulant 60a may include LSR or FKM.

In some arrangements, the encapsulant 60a may be configured to be adjustable. The encapsulant 60a may each be soft and flexible enough for the object to be worn comfortably for an extended time period. In some arrangements, the encapsulant 60a may each be relatively more resistant to stress, impact, twisting or other physical or structural changes. For example, the encapsulant 60a may each be resilient, such that, after being squeezed or deformed, an encapsulant can return to its original state. In some arrangements, the encapsulant 60a may each flexibly adjust its shape to conform to the body of a user. In some arrangements, the encapsulant 60a may be configured to directly contact the body of a user. The encapsulant 60a may each be bio-compatible. For example, the encapsulant 60a may each not being toxic, injurious, or physiologically reactive and not causing immunological rejection.

The encapsulant 60a may have a thickness T1, which may be defined as a distance between the surface 10s2 of the circuit structure 10 and the surface 60s1 of the encapsulant 60a. The conductive element 50 may have a vertical distance L1 between the top of the conductive element 50 and the surface 10s2 of the circuit structure 10. In some arrangements, the distance L1 may be greater than the thickness T1.

In some arrangements, the flexible conductive layer 70a (or sensing element or conductive layer) may be disposed on or over the surface 60s1 of the encapsulant 60a. In some arrangements, the flexible conductive layer 70a may be electrically connected to the conductive element 50. In some arrangements, a portion of the conductive element 50 (e.g., the top portion of the conductive element 50) may be embedded within the flexible conductive layer 70a. In some arrangements, the flexible conductive layer 70a may be electrically connected to the circuit structure 10 through the conductive element 50. In some arrangements, the flexible conductive layer 70a may be electrically connected to the electronic component 20a (electronic component 20b) through the conductive element 50 and the circuit structure 10. In some arrangements, the flexible conductive layer 70a may be electrically connected to the electrical connector 30 through the conductive element 50 and the circuit structure 10. The flexible conductive layer 70a may have a surface 70s1 (or a lower surface), a surface 70s2 (or an upper surface), and a surface 70s3 (or a lateral surface) extending between the surface 70s1 and surface 70s2. The surface 70s1 may be in contact with the surface 60s1. The surface 70s2 may be opposite to the surface 70s1 and function as a sensing surface configured to sense or detect one or more signals (biological signals or physiological signals) from the surroundings of the electronic device 1a.

In some arrangements, the flexible conductive layer 70a may be an electrode, a thermistor, a pressure sensor, a proximity sensor, a motion sensor, an acoustic sensor, a smell sensor, a particle sensor, a humidity sensor, an optical transmitter, an optical receiver, an optical transceiver, or a combination thereof. In some arrangements, the flexible conductive layer 70a may be used to detect or collect one or more signals (which may be single-ended signals or differential signals) or pieces of information external to the electronic device 1a. For example, the flexible conductive layer 70a may be used to detect temperature, air pressure, smell, particle, sound, light, humidity, or other environmental variables. In some arrangements, the flexible conductive layer 70a may be used to detect one or more biological signals or physiological signals of a user. For example, the biological signals detected by the flexible conductive layer 70a may be further processed by the electronic component 20a and/or electronic component 20b to determine a biological parameter of a user, such as a pulse travel time (PTT), an electroencephalogram (EEG), electrocardiogram (ECG), electromyogram (EMG), electrooculogram (EOG), galvanic skin response (GSR), sweat composition, pH, heart rate variability (HRV), or other biologically-relevant information associated with the object. In some arrangements, the electronic component 20a and/or electronic component 20b may be configured to process (e.g., analysis, modify, synthesize, convert to a digital signal, and amplify, etc.), to store, and/or to transmit the detected biological signals.

In some arrangements, the flexible conductive layer 70a may include a conductive paste, conductive adhesive, or other flexible, flowable, bendable, or shapeable materials. In some arrangements, the flexible conductive layer 70a may include conductive fillers (or particles) and a non-conductive medium. The conductive filler may include copper (Cu), gold (Au), silver (Ag), aluminum (Al), chromium (Cr), tin (Sn), nickel (Ni), or other combinations of two or more thereof. The non-conductive medium may include, for example, resin, polymer, rubber, polyester, polyurethane, or other suitable materials such as an elastic material, a soft material, a sponge-like material, or a flexible material. In some arrangements, the flexible conductive layer 70a may include LSR or FKM. In some arrangements, the resistance of the flexible conductive layer 70a may be less than that of the conductive element 50. For example, the resistance of the flexible conductive layer 70a may be about 10³ V/A. The resistance of the conductive element 50 may be less than 10³ V/A.

The flexible conductive layer 70a may have a thickness T2, which may be defined as a distance between the surface 70s1 and surface 70s2. In some arrangements, the thickness T1 may be greater than the thickness T2. In this case, the encapsulant 60a may be configured to enhance the durability of the electronic device 1a. In some arrangements, the surface 70s3 of the flexible conductive layer 70a may be substantially aligned with the surface 60s2 of the encapsulant 60a.

In a comparative example, electronic components (e.g., dies) and a sensing surface are disposed at the same side of a carrier, and a flexible conductive material (e.g., a sensing electrode) covers the electronic components. In this configuration, the electronic components may occupy the space intended for the flexible conductive material, resulting in a less uniform distribution and a larger resistance in the conductive path. In this arrangement, the electronic component 20a (or electronic component 20b) and the flexible conductive layer 70a are disposed on opposite sides of the circuit structure 10. Accordingly, the aforementioned issues are avoided. Additionally, the conductive element 50 may possess high conductivity and occupy a smaller space, improving the electrical conductivity of a bio-signal from the flexible conductive layer 70a. This allows for relatively uniform distribution of the conductive fillers in the flexible conductive layer 70a. Consequently, signal noise can be reduced, transmission loss problems can be solved, and sensing quality can be improved.

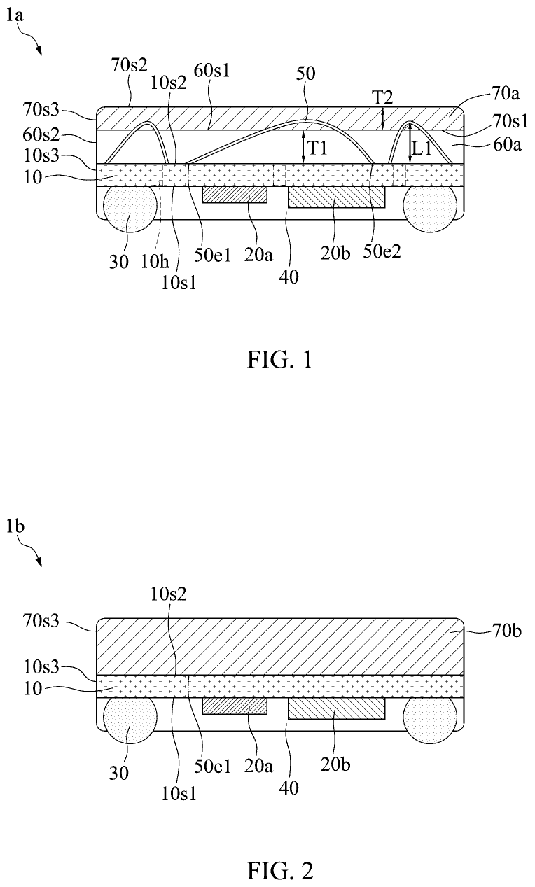

FIG. 2 illustrates a cross-sectional view of an electronic device 1b in accordance with some arrangements of the present disclosure. The electronic device 1b is similar to the electronic device 1a in FIG. 1 except for the differences described as follows.

In some arrangements, the conductive elements 50 may be omitted from the electronic device 1b. In some arrangements, the encapsulant 60a may be omitted from the electronic device 1b. In some arrangements, the flexible conductive layer 70b may be disposed on or over the surface 10s2 of the circuit structure 10. In some arrangements, the flexible conductive layer 70b may be in contact with the surface 10s2 of the circuit structure 10. In some arrangements, the surface 70s3 of the flexible conductive layer 70b may be substantially aligned with the surface 10s3 of the circuit structure 10. By omitting the conductive element 50 in this configuration, the formation of the flexible conductive layer 70b may proceed without obstacles during manufacturing processes, allowing for a more uniform distribution of the conductive fillers.

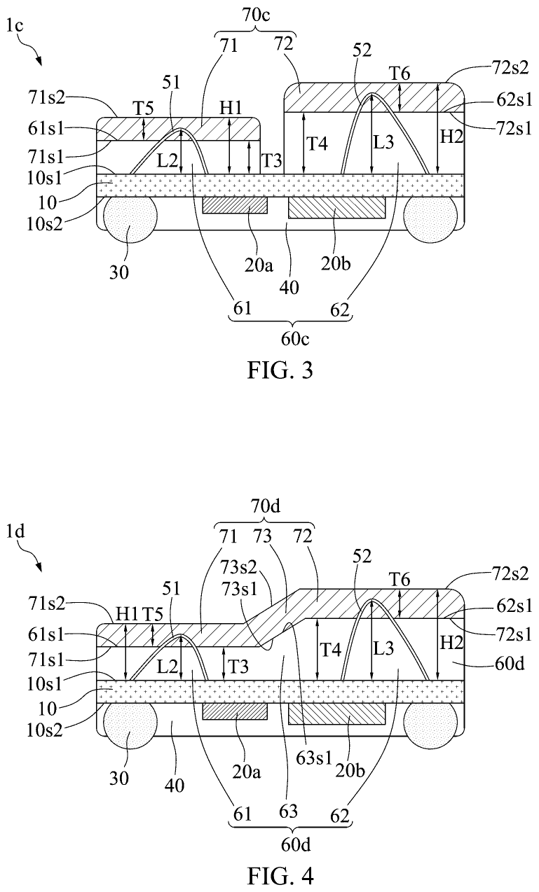

FIG. 3 illustrates a cross-sectional view of an electronic device 1c in accordance with some arrangements of the present disclosure. The electronic device 1c is similar to the electronic device 1a in FIG. 1 except for the differences described as follows.

In some arrangements, the encapsulant 60c may include a portion 61 and a portion 62. In some arrangements, the portion 61 may be spaced apart from the portion 62. In some arrangements, the portion 61 may be spaced apart from the portion 62 by an air. In some arrangements, the portion 61 may be spaced apart from the portion 62 by a dielectric material (not shown). The portion 61 may have a surface 61s1 (or an upper surface). The portion 62 may have a surface 62s2 (or an upper surface). The portion 61 may have a thickness T3, which is defined as a distance between the surface 10s2 of the circuit structure 10 and the surface 61s1 of the portion 61. The portion 62 may have a thickness T4, which is defined as a distance between the surface 10s2 of the circuit structure 10 and the surface 62s1 of the portion 62. In some arrangements, the thickness T3 may be different from the thickness T4.

In some arrangements, the flexible conductive layer 70c may include a portion 71 and a portion 72. In some arrangements, the portion 71 may be spaced apart from the portion 72. In some arrangements, the portion 71 may be spaced apart from the portion 72 by an air. In some arrangements, the portion 71 may be spaced apart from the portion 72 by a dielectric material (not shown). The portion 71 may have a surface 71s1 (or a lower surface) and a surface 71s2 (or an upper surface). The portion 72 may have a surface 72s1 (or a lower surface) and a surface 72s2 (or an upper surface). In some arrangements, the surface 71s1 of the portion 71 may be at a level (or an elevation), with respect to the surface 10s2, different from that of the surface 72s1 of the portion 72. In some arrangements, the surface 71s2 of the portion 71 may be at a level (or an elevation), with respect to the surface 10s2, different from that of the surface 72s2 of the portion 72. In some arrangements, the surface 71s2 of the portion 71 may be at a level (or an elevation), with respect to the surface 10s2, lower than that of the surface 62s1 of the portion 62. The surface 72s2 may be substantially parallel to the surface 71s2.

The portion 71 may have a thickness T5, which is defined as a distance between the surface 71s1 and surface 71s2. The portion 72 may have a thickness T6, which is defined as a distance between the surface 10s2 of the circuit structure 10 and the surface 72s1 of the portion 72. In some arrangements, the thickness T5 may be different from the thickness T6. For example, the thickness T6 may be greater than the thickness T5. In other embodiments, the thickness T5 may be substantially equal to the thickness T6. The portion 71 may have a length H1 (or elevation) between the surface 71s2 and the surface 10s2 of the circuit structure 10. The portion 72 may have a length H2 (elevation) between the surface 72s2 and the surface 10s2 of the circuit structure 10. In some arrangements, the length H1 may be different from the length H2.

The electronic device 1c may include a conductive element 51 and a conductive element 52. The conductive element 51 may be embedded within the portion 61. A portion of the conductive element 51 (e.g., the top portion of the conductive element 51) may be embedded within the portion 71. The conductive element 51 may be spaced apart from the portion 62. The conductive element 51 may be electrically connected to the portion 71. The conductive element 52 may be embedded within the portion 62. A portion of the conductive element 52 (e.g., the top portion of the conductive element 52) may be embedded within the portion 72. The conductive element 52 may be spaced apart from the portion 61. The conductive element 52 may be electrically connected to the portion 72. The conductive element 51 may have a vertical distance L2 between the top of the conductive element 51 and the surface 10s2 of the circuit structure 10. The conductive element 52 may have a vertical distance L3 between the top of the conductive element 52 and the surface 10s2 of the circuit structure 10. In some arrangements, the distance L2 may be different from the thickness L3.

The portion 71 may be configured to detect or sense a first signal (e.g., a biological signal or physiological signal) of a user. The portion 72 may be configured to detect or sense a second signal (e.g., a biological signal or physiological signal) of a user. In some arrangements, the first signal is different from the second signal. For example, the portion 71 and portion 72 may be attached different portions of a user and detect different bio-signals from said portions.

FIG. 4 illustrates a cross-sectional view of an electronic device 1d in accordance with some arrangements of the present disclosure. The electronic device 1d is similar to the electronic device 1c in FIG. 3 except for the differences described as follows.

In some arrangements, the encapsulant 60d may include a portion 63. In some arrangements, the portion 63 may connect the portion 61 and portion 62. In some arrangements, the portion 63 may have a surface 63s1 (or an upper surface) spaced apart from the circuit structure 10. The surface 63s1 may connect the surface 61s1 and surface 62s1. In some arrangements, the surface 63s1 may be a slanted surface. In some arrangements, the surface 63s1 may be nonparallel to the surface 61s1. In some arrangements, the surface 63s1 may be nonparallel to the surface 62s1.

In some arrangements, the flexible conductive layer 70d may include a portion 73. In some arrangements, the portion 73 may connect the portion 71 and portion 72. In some arrangements, the portion 73 may have a surface 73s1 (or a lower surface) and surface 73s2 (or an upper surface). The surface 73s1 may connect the surface 71s1 and surface 72s1. In some arrangements, the surface 73s1 may be a slanted surface. The surface 73s2 may connect the surface 71s2 and surface 72s2. In some arrangements, the surface 73s2 may be a slanted surface. In this arrangement, the sensing surface of the flexible conductive layer 70d may be positioned at varying elevations, which could be more appropriate or better suited for certain wearable devices.

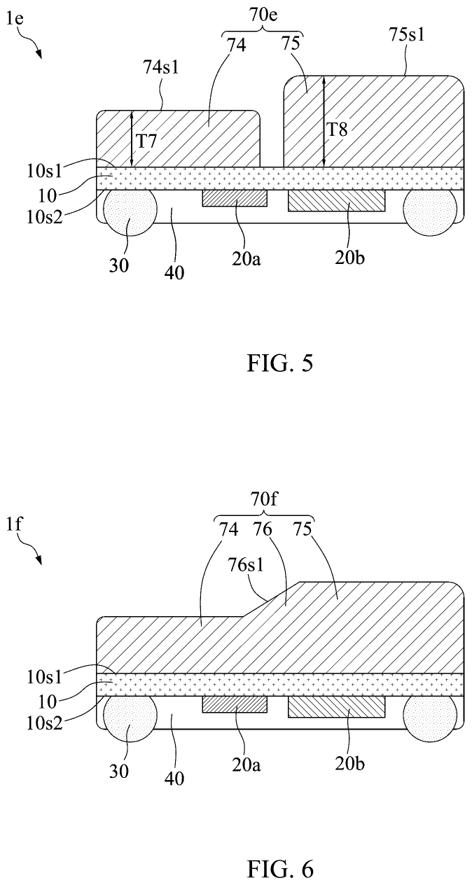

FIG. 5 illustrates a cross-sectional view of an electronic device 1e in accordance with some arrangements of the present disclosure. The electronic device 1e is similar to the electronic device 1c in FIG. 3 except for the differences described as follows.

In some arrangements, the conductive element 51 and conductive element 52 may be omitted from the electronic device 1e. In some arrangements, the encapsulant 60c may be omitted from the electronic device 1e. The flexible conductive layer 70e may have a portion 74 and a portion 75. In some arrangements, the portion 74 may be spaced apart from the portion 75. In some arrangements, the portion 74 may be in contact with the surface 10s2 of the circuit structure 10. In some arrangements, the portion 75 may be in contact with the surface 10s2 of the circuit structure 10. The portion 74 may have a surface 74s1 (or an upper surface). The portion 75 may have a surface 75s1 (or an upper surface). The portion 74 may have a thickness T7, which may be defined as a distance between the surface 74s1 of the portion 74 and the surface 10s2 of the circuit structure 10. The portion 75 may have a thickness T8, which may be defined as a distance between the surface 75s1 of the portion 74 and the surface 10s2 of the circuit structure 10. In some arrangements, the thickness T7 may be different from the thickness T8. By omitting the conductive element 51 and conductive element 52 in this configuration, the formation of the flexible conductive layer 70e may proceed without obstacles during manufacturing processes, allowing for a more uniform distribution of the conductive fillers.

FIG. 6 illustrates a cross-sectional view of an electronic device 1f in accordance with some arrangements of the present disclosure. The electronic device 1f is similar to the electronic device 1d in FIG. 4 except for the differences described as follows.

In some arrangements, the conductive element 51 and conductive element 52 may be omitted from the electronic device 1f. In some arrangements, the encapsulant 60d may be omitted from the electronic device 1f. The flexible conductive layer 70e may have a portion 76. The portion 76 may connect the portion 74 and portion 75. The portion 76 may have a surface 76s1 (or an upper surface). In some arrangements, the surface 76s1 may be a slanted surface. In some arrangements, the surface 76s1 of the portion 76 may be nonparallel to the surface 10s2 of the circuit structure 10. By omitting the conductive element 51 and conductive element 52 in this configuration, the formation of the flexible conductive layer 70f may proceed without obstacles during manufacturing processes, allowing for a more uniform distribution of the conductive fillers. As a result, the conductive fillers may distribute more uniformly. In this arrangement, the sensing surface of the flexible conductive layer 70f may be positioned at varying elevations, which could be more appropriate or better suited for certain wearable devices.

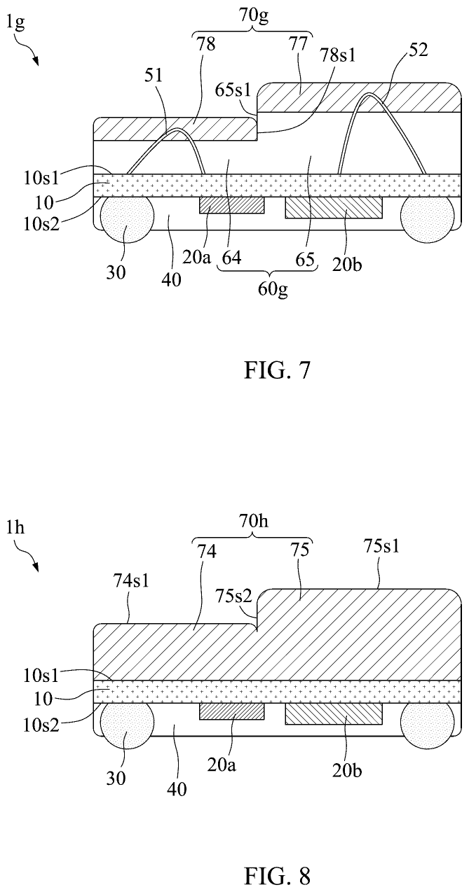

FIG. 7 illustrates a cross-sectional view of an electronic device 1g in accordance with some arrangements of the present disclosure. The electronic device 1g is similar to the electronic device 1a in FIG. 1 except for the differences described as follows.

In some arrangements, the encapsulant 60g may include a portion 64 and a portion 65. In some arrangements, the thickness of the portion 64 may be different from the portion 65. In some arrangements, the portion 64 may be connected to the portion 65. For example, the portion 64 may be in contact with the portion 65.

In some arrangements, the flexible conductive layer 70g may include a portion 77 and a portion 78. In some arrangements, the portion 78 may be disposed on or over the portion 64. In some arrangements, the portion 77 may be disposed on or over the portion 65. In some arrangements, the portion 77 may be spaced apart from the portion 78. In some arrangements, the portion 78 may be in contact with the portion 65. In some arrangements, a surface 78s1 (or a lateral surface) of the portion 78 may be in contact with the lateral surface of surface 65s1 (or a lateral surface) of the portion 65. In some arrangements, a portion of the surface 65s1 may be exposed by the portion 78. In some arrangements, a portion of the surface 65s1 may be covered by the portion 78.

FIG. 8 illustrates a cross-sectional view of an electronic device 1h in accordance with some arrangements of the present disclosure. The electronic device 1h is similar to the electronic device 1g in FIG. 7 except for the differences described as follows.

In some arrangements, the encapsulant 60g may be omitted from the electronic device 1h. In some arrangements, the flexible conductive layer 70h may include the portion 74 and the portion 75. In some arrangements, the portion 74 may be in contact with the portion 75. The portion 74 and the portion 75 may define a step. For example, the flexible conductive layer 70g may include a surface 75s2 (or a lateral surface) extending between the surface 74s1 and the surface 75s1. By omitting the conductive element 51 and conductive element 52 in this configuration, the formation of the flexible conductive layer 70h may proceed without obstacles during manufacturing processes, allowing for a more uniform distribution of the conductive fillers. In this arrangement, the sensing surface of the flexible conductive layer 70h may be positioned at varying elevations, which could be more appropriate or better suited for certain wearable devices.

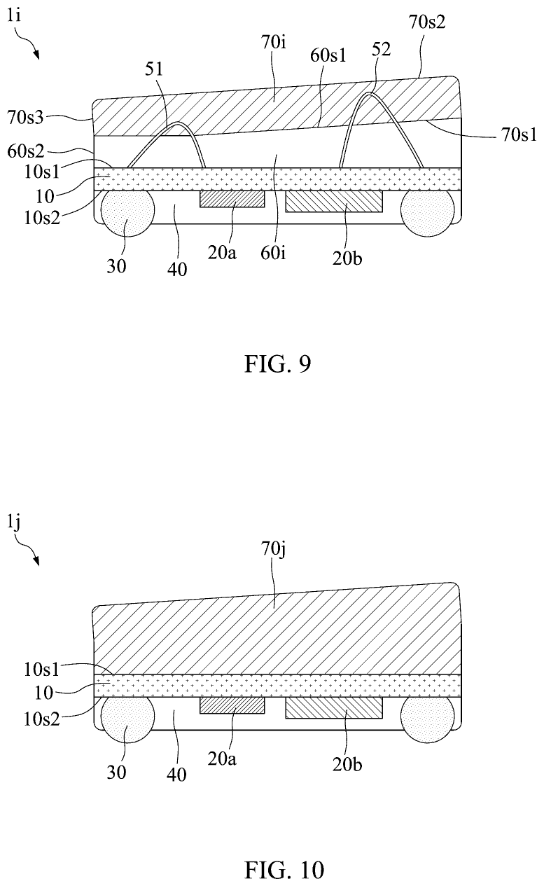

FIG. 9 illustrates a cross-sectional view of an electronic device 1i in accordance with some arrangements of the present disclosure. The electronic device 1i is similar to the electronic device 1a in FIG. 1 except for the differences described as follows.

In some arrangements, the surface 60s1 of the encapsulant 60i may be a slanted surface. In some arrangements, the thickness of the encapsulant 60i may be nonuniform. In some arrangements, the surface 70s1 of the flexible conductive layer 70i may be a slanted surface. In some arrangements, the surface 70s2 of the flexible conductive layer 70i may be a slanted surface. In some arrangements, the surface 70s1 may be substantially parallel to the surface 70s2. In some arrangements, the slope of the surface 60s2 of the encapsulant 60i may be different from the surface 70s3 of the flexible conductive layer 70i. For example, the angle between the normal of the surface 10s2 of the circuit structure 10 and the surface 60s2 of the encapsulant 60i may be less than the angle between the normal of the surface 10s2 of the circuit structure 10 and the surface 70s3 of the flexible conductive layer 70i. In this arrangement, the sensing surface of the flexible conductive layer 70i may be positioned at varying elevations, which could be more appropriate or better suited for certain wearable devices.

FIG. 10 illustrates a cross-sectional view of an electronic device 1j in accordance with some arrangements of the present disclosure. The electronic device 1j is similar to the electronic device 1i in FIG. 9 except for the differences described as follows.

In some arrangements, the encapsulant 60i may be omitted from the electronic device 1j. The flexible conductive layer 70j may be in contact with the surface 10s2 of the circuit structure 10. By omitting the conductive element 51 and conductive element 52 in this configuration, the formation of the flexible conductive layer 70j may proceed without obstacles during manufacturing processes, allowing for a more uniform distribution of the conductive fillers.

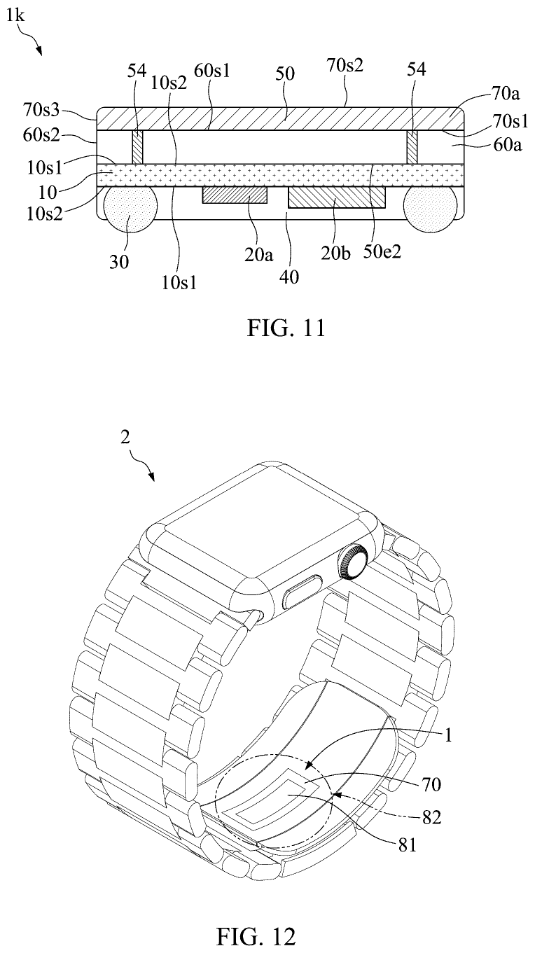

FIG. 11 illustrates a cross-sectional view of an electronic device 1k in accordance with some arrangements of the present disclosure. The electronic device 1k is similar to the electronic device 1a in FIG. 1 except for the differences described as follows.

In some arrangements, the electronic device 1k may include conductive element 52. In some arrangements, the conductive element 52 may be a conductive pillar extending between the surface 10s2 of the circuit structure 10 and the surface 70s1 of the flexible conductive layer 70a. The conductive element 52 may be electrically connected to the circuit structure 10. The conductive element 52 may be electrically connected to the flexible conductive layer 70a. In some arrangements, the flexible conductive layer 70a may include copper (Cu) or other conductive materials, such as aluminum (Al), chromium (Cr), tin (Sn), gold (Au), silver (Ag), nickel (Ni), stainless steel, another metal, or a mixture, an alloy, or other combinations of two or more thereof. In this arrangement, the conductive element 52 may be configured to robust the overall structure of the electronic device 1k.

FIG. 12 illustrates a perspective view of a wearable device 2 in accordance with some arrangements of the present disclosure.

In some arrangements, the wearable device 2 may include a smart watch or the like. In some arrangements, the wearable device 2 may include a curved portion 82. The curved portion 82 may have a curved profile (e.g., surface or edge). In some arrangements, the curved portion 82 may be configured to attach to a user. In some arrangements, the wearable device 2 may include an electronic device 1 within the curved portion 82. In some arrangements, the electronic device 1 may include one or more of the electronic devices 1a to 1k. In some arrangements, the electronic device 1 may be secured or fixed to an opening of the wearable device 2. For example, the electronic device 1 may be mechanically joined or connected to the opening of the wearable device 2.

For example, the electronic device 1 and the opening of the wearable device 2 may have a mechanical or magnetic means to resist or arrest the movement of the electronic device 1. The mechanical or magnetic means may prevent unintended separation of the electronic device 1 and the opening of the wearable device 2. The mechanical or magnetic means may include locking elements, fastening elements, retaining elements, etc. More specifically, the mechanical or magnetic means may include a pin, a post, a spring, a plugger, a buffer, a snap, a clip, a contour, etc.

In some arrangements, the electronic device 1 may be configured to constructively form a part of the wearable device 2. In some arrangements, the electronic device 1 may be attached, removed, and reattached to the wearable device 2. In some arrangements, the electronic device 1 may be configured to provide or support auxiliary or supplementary function or operation of the wearable device 2. The wearable device 2 may be configured to be worn by and/or attached to an object (or a wearing object) or a target. The wearable device 2 may be configured to connect the sensing area 81 of the electronic device 1 to the object. The wearable device 2 may be configured to bring the sensing area 81 of the electronic device 1 to be closer to the object. The wearable device 2 may be configured to keep or define a distance between the sensing area 81 of the electronic device 1 and the object. In some arrangements, an outer surface of the electronic device 1 may be conformal to a wearing surface of a structure (such as a frame, a housing, a supporting or an accessory part) of the wearable device 2 accommodating the electronic device 1. In some arrangements, the electronic device 1 may be disposed within or adjacent to the curved portion 82.

Furthermore, the shape or dimension of the electronic device 1 can be adjusted to adapt to the wearable device 2. For example, if the wearable device 2 has a metallic strap, the sensing area 81 of the flexible conductive layer 70 may be covered or surrounded by the flexible conductive layer 70 and separated from the metallic strap by the flexible conductive layer 70. Therefore, the flexible conductive layer 70 may help reducing signal interference, and the sensing quality can be improved.

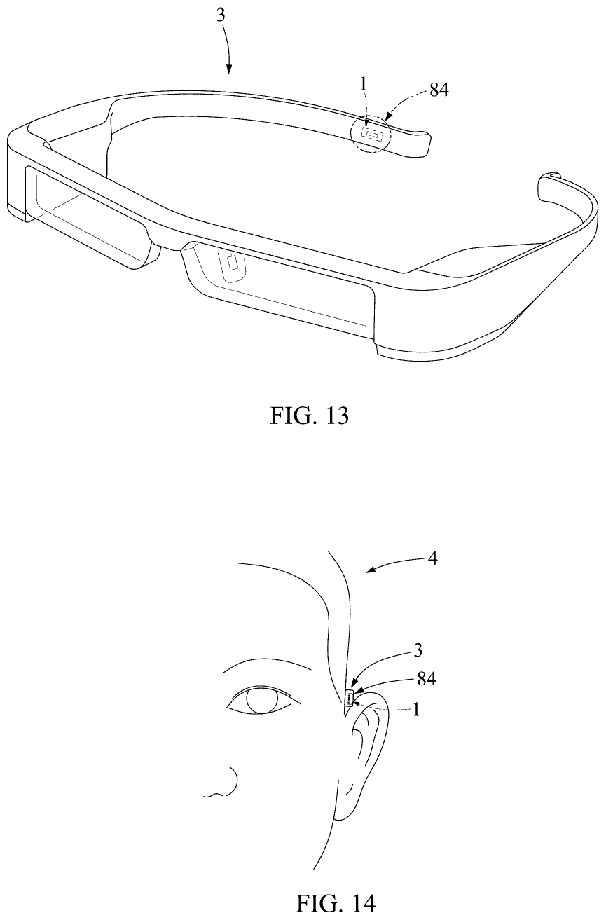

FIG. 13 illustrates a perspective view of a wearable device 3 in accordance with some arrangements of the present disclosure.

In some arrangements, the wearable device 3 may include a curved portion 84. The curved portion 84 may have a curved profile (e.g., surface or edge). In some arrangements, the curved portion 84 may be configured to attach to a user. In some arrangements, the wearable device 3 may include the electronic device 1 within the curved portion 84. In some arrangements, the electronic device 1 may include one or more of the electronic devices 1a to 1k.

FIG. 14 illustrates a perspective view of a wearable device on a user 4 in accordance with some arrangements of the present disclosure.

As shown in FIG. 14, the curved portion 84 of the wearable device 3 may be attached to the user 4 to sense or detect signals or pieces of information, such as biological signals, physiological signals, motions (e.g., body motions of the human or animal), and/or environmental information in a vicinity of an object. In other arrangements, other wearable devices that include the electronic device 1 may replace the wearable device 3.

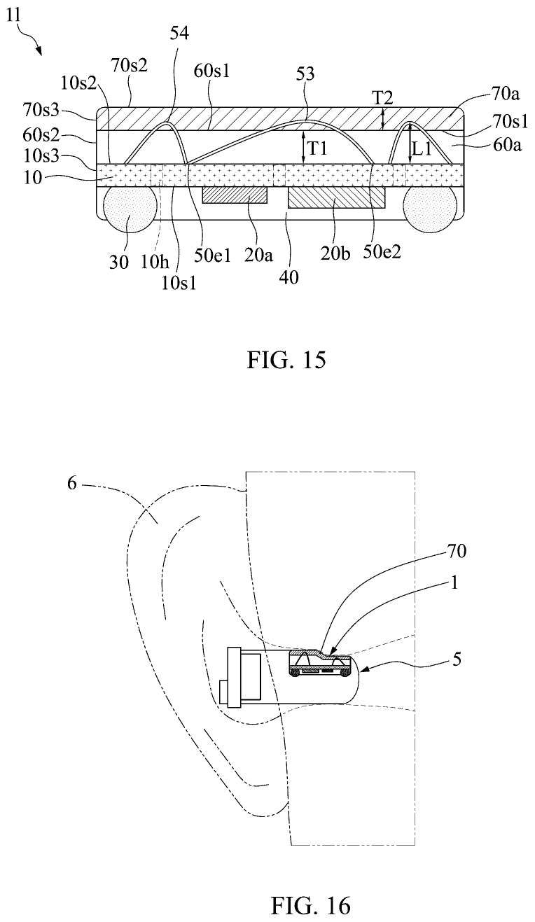

FIG. 15 illustrates a cross-sectional view of an electronic device 1l in accordance with some arrangements of the present disclosure. The electronic device 1l is similar to the electronic device 1a in FIG. 1 except for the differences described as follows.

In some arrangements, some of the conductive elements may be in directly contact with each other. For example, a conductive element 53 may be in contact with a conductive element 54. The conductive element 53 may be electrically connected to the conductive element 54. In some arrangements, the conductive elements 53 and 54 may be configured to transmit the same signal (e.g., biological signals, physiological signals, or other signals). The connection of the conductive elements 53 and 54 may enhance the conductivity of signal transmission.

FIG. 16 illustrates a perspective view of a wearable device 5 on a user in accordance with some arrangements of the present disclosure. FIG. 16 illustrates an example that the wearable device 5 is worn by a user in accordance with some arrangements of the present disclosure.

The wearable device 5 may include the electronic device 1. In some arrangements, the electronic device 1 may have a surface (e.g., the surfaces 71s1, 72s2, and 73s2 as shown in FIG. 4) configured to be in contact with a user 6. In some arrangements, the sensing surface of the flexible conductive layer 70 (e.g., the flexible conductive layer 70d as shown in FIG. 4) may be configured to be in contact with a user 6. In some arrangements, the sensing surface of the flexible conductive layer 70 may be exposed to the wearable device 5. In some arrangements, the wearable device 5 may be flexibly adjusted according to a shape, a size, and/or a profile of a user's skin (such as a user's ear canal). In some arrangements, the surface of the electronic device 1 may be flexibly adjusted according to a shape, a size, and/or a profile of a user's skin (such as a user's ear canal).

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a circuit structure having a first surface and a second surface opposite to the first surface;
an electronic component under the first surface;
a flexible conductive layer over the second surface; and
a conductive element extending toward a direction far away from the second surface and connected to the flexible conductive layer, the conductive element is embedded within at least two different materials.

2. The electronic device of claim 1, further comprising:
a first encapsulant encapsulating the conductive element, wherein the conductive element is embedded within the flexible conductive layer and the first encapsulant.

3. The electronic device of claim 2, further comprising:
an additional conductive element extending toward the direction far away from the second surface and connected to the flexible conductive layer, wherein the conductive element is in contact with the additional conductive element.

4. The electronic device of claim 2, further comprising:
a second encapsulant under the first surface of the circuit structure and encapsulating the electronic component.

5. The electronic device of claim 4, wherein the circuit structure comprises a terminal disposed under the first surface of the circuit structure and configured to be electrically connected to an external device.

6. The electronic device of claim 5, wherein the electronic device is configured to be disposed within a curved portion of a wearable device, and the flexible conductive layer is configured to be exposed by the wearable device.

7. The electronic device of claim 5, wherein the terminal is exposed by the second encapsulant.

8. An electronic device, comprising:
a circuit structure having a first surface and a second surface;
an electronic component under the first surface;
a sensing element over the second surface and spaced apart from the circuit structure; and
a first conductive element between the sensing element and the circuit structure.

9. The electronic device of claim 8, wherein a resistance of the first conductive element is less than a resistance of the sensing element.

10. The electronic device of claim 8, further comprising:
an encapsulant encapsulating the first conductive element, wherein a thickness of the sensing element is less than a thickness of the encapsulant.

11. The electronic device of claim 10, wherein the conductive element is protruded from the encapsulant.

12. The electronic device of claim 8, wherein the sensing element comprises a first part and a second part spaced apart from the first part, the first part is configured to transceive a first signal, and the second part is configured to transceive a second signal different from the first signal.

13. The electronic device of claim 12, further comprising:
a second conductive element, wherein the first conductive element is electrically connected to the first part, and the second conductive element is electrically connected to the second part of the sensing element.

14. An electronic device, comprising:
a circuit structure having a first surface and a second surface;
an electronic component under and electrically connected to the first surface; and
a conductive layer over the second surface, wherein the conductive layer is configured to detect a bio-signal and has a surface, spaced apart from the circuit structure, with different elevations with respect to the second surface of the circuit structure.

15. The electronic device of claim 14, wherein the conductive layer includes a first part with a first elevation and a second part with a second elevation different from the first elevation with respect to the second surface of the circuit structure.

16. The electronic device of claim 15, wherein the conductive layer has a third part connecting the first part and the second part, and the third part has an upper surface connected to a first substantially flat surface and a second substantially flat surface.

17. The electronic device of claim 15, further comprising:
a first encapsulant disposed between the conductive layer and the circuit structure,
wherein the first encapsulant has a first portion with a first thickness and a second portion with a second thickness different from the first thickness, the first portion of the first encapsulant is connected to the first part of the conductive layer, and the second portion of the first encapsulant is connected to the second part of the conductive layer.

18. The electronic device of claim 17, wherein the first portion is spaced apart from the second portion.

19. The electronic device of claim 17, wherein the conductive layer has a substantially uniform thickness conformally on the first encapsulant.

20. The electronic device of claim 14, further comprising:
a first encapsulant supporting the conductive layer, wherein a portion of the first encapsulant is in an elevation higher than that of the conductive layer.
